(19) United States
(12) Patent Application Publication
(10) Pub. No.: US 2015/0123687 A1
(43) Pub. Date: May 7, 2015

(54) TEST PROBE AND MACHINING METHOD THEREOF

(71) Applicant: LEENO INDUSTRIAL INC., Busan (KR)

(72) Inventor: Chae Yoon Lee, Busan (KR)

(21) Appl. No.: 14/400,104

(22) PCT Filed: May 23, 2013
(86) PCT No.: PCT/KR2013/004504

§ 371 Date: Nov. 10, 2014

(30) Foreign Application Priority Data
Jun. 13, 2012 (KR) 10-2012-0062975

(51) Int. Cl. G01R 1/04; G01R 31/26

(52) U.S. Cl. CPC G01R 1/0416; G01R 31/2607
USPC 324/754.11; 29/558

(57) ABSTRACT

Disclosed are a test probe and a machining method of a test probe, the test probe including a plunger end part contacting a tested contact point, the plunger end part including a plurality of tips protruding toward the tested contact point, and at least one of the plurality of tips is a higher tip and at least another one of the plurality of tips is a lower tip that is lower than the higher tip.

### FIELD OF THE INVENTION

Apparatuses and methods consistent with the exemplary embodiments relate to a test probe and a machining method thereof .

### BACKGROUND ART

Generally, a test process is performed during a manufacturing process of semiconductors to measure electric characteristics in checking defects of the semiconductors. In the test process, a test device for checking the electric characteristics of the semiconductor, and a test probe for electrically connect a tested contact point of the semiconductor and a testing contact point of the test device are used.

FIG. 1 illustrates an example of a test probe that is generally used to test a semiconductor chip. As shown therein, a test probe 10 includes upper and lower plungers 12 and 16 which includes a metal conductive material and is shaped like a bar, a barrel 14 which accommodates the upper and lower plungers 12 and 16 therein, and a spring (not shown) which elastically supports the upper and lower plungers 12 and 16 within the barrel 14.

An end part of the upper plunger 12 generally forms a plunger end part 20 shaped like a crown to improve contact with a tested contact point of a semiconductor and reduce a contact resistance. As shown in FIG. 2, the plunger end part 20 includes a plurality of tips 22, a peak of which is sharp and penetrates into the tested contact point of a soft metal material during test and makes a more accurate electrical contact to ensure reliability of the test. As shown in FIG. 3, the plurality of tips 22 is formed at the same height.

The tips 22 which protrude at the same height are gradually worn and become blunt due to repeated tests. In particular, the tips 22 are worn at a similar level since they are formed at the same height. Accordingly, as the tips 22 are worn and become blunt, the peak cannot penetrate into the metal of the tested contact point so that the electric contact resistance value is unstable. This drastically damages the reliability of the test, and reduces the life of the test probe.

### DISCLOSURE

### Technical Problem

Accordingly, one or more exemplary embodiments provide a test probe which allows at least a part of tips of the test probe to maintain its sharpness even if another part of the tips is worn.

Another exemplary embodiment is to provide a test probe whose life is capable of being extended while test reliability is maintained.

### Technical Solution

According to aspect of an exemplary embodiment, there is provided a test probe including a plunger end part which contacts a tested contact point, and a plurality of tips which is provided in the plunger end part and protruds toward the tested contact point, and at least one of the plurality of tips is a higher tip and at least another one of the plurality of tips is a lower tip that is lower than the higher tip.

The higher tip and the lower tip maybe alternately arranged along a circumferential direction.

A central tip which is not higher than the higher tip may be provided in a central area of the plunger end part.

The tips may be arranged in a circumferential direction leaving a blank area in a center without a tip.

According to aspect of another exemplary embodiment, there is provided a machining method of a test probe which includes a plunger end part contacting a tested contact point, the method including: processing a circumferential surface of the plunger end part at a predetermined inclination angle to form a tapered inclined surface; and performing a plurality of parallel V-cuttings in horizontal and vertical directions with respect to an end surface of the plunger end part at intervals to form at least one higher tip and at least one lower tip that is lower than the higher tip.

The plunger end part may further comprise a hole along a central axis.

The machining method may further comprise drilling the plunger end part along a central axis before or after processing operation of the tapered inclined surface processing operation.

The tapered inclined surface may comprise a beheaded conical surface.

The tapered inclined surface may comprise a beheaded multi-angular pyramid surface.

### DESCRIPTION OF DRAWINGS

The above and/or other aspects will become apparent and more readily appreciated from the following description of the exemplary embodiments, taken in conjunction with the accompanying drawings, in which:

FIG. 1 illustrates a test probe which is generally used;

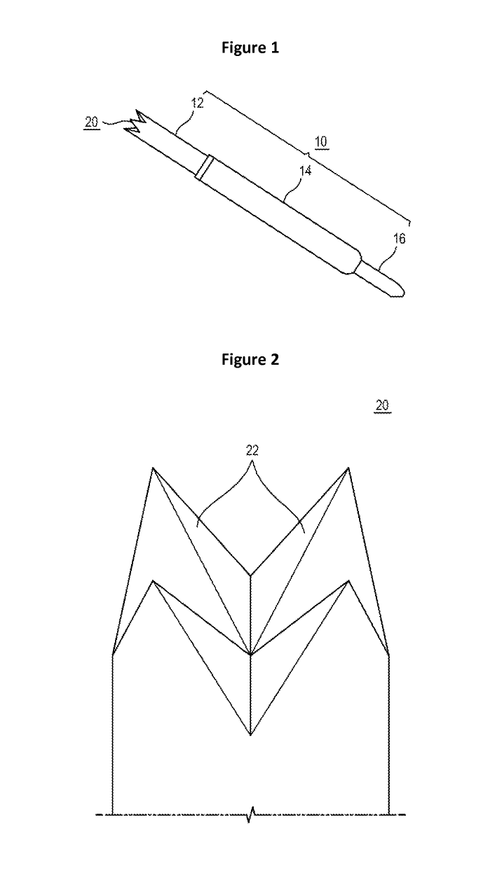

FIGS. 2 and 3 are enlarged views of a conventional plunger end part;

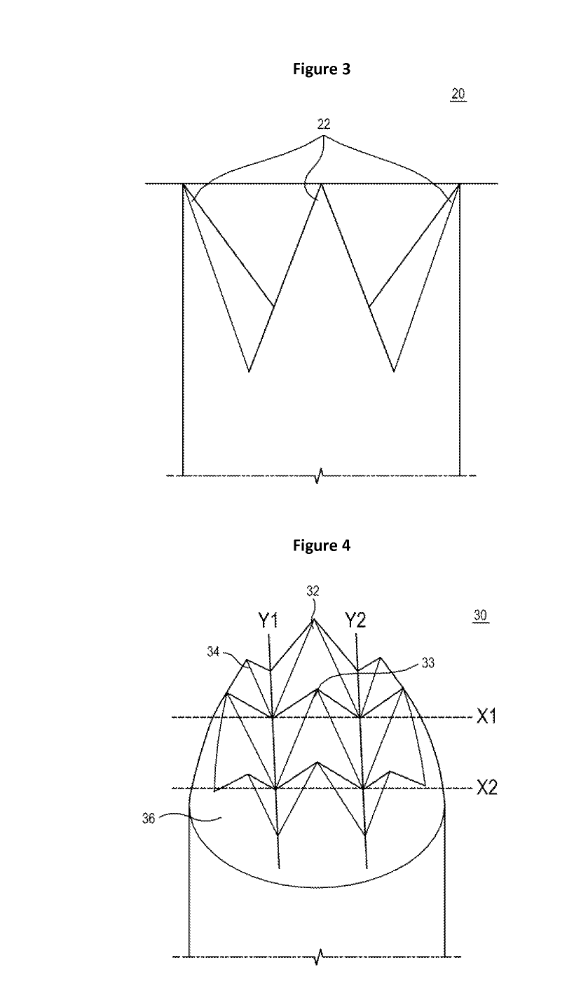

FIGS. 4 and 5 are enlarged views of plunger end parts according to exemplary embodiments of the present invention;

FIGS. 6 and 7 are enlarged views of plunger end parts according to another exemplary embodiments of the present invention; and

FIG. 8 is a flow chart illustrating a machining method of a test probe according to an exemplary embodiment of the present invention.

### BEST MODE

Below, exemplary embodiments will be described in detail with reference to accompanying drawings so as to be easily realized by a person having ordinary knowledge in the art. The exemplary embodiments maybe embodied in various forms without being limited to the exemplary embodiments set forth herein. Descriptions of well-known parts are omitted for clarity, and like reference numerals refer to like elements throughout.

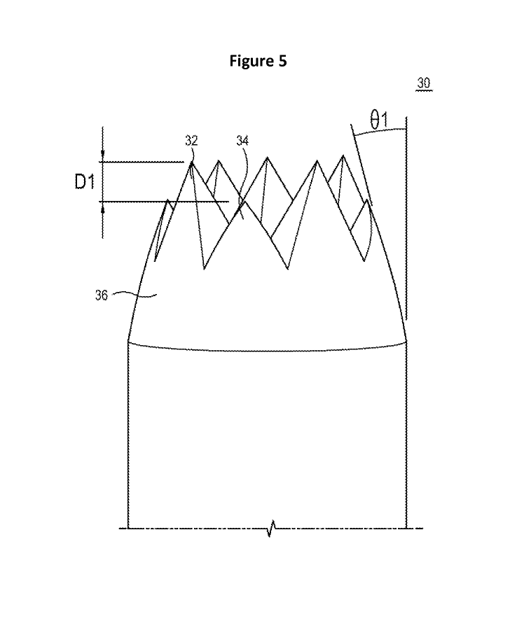

FIGS. 4 and 5 are enlarged views of an end part of a plunger of a test probe according to an exemplary embodiment, in which FIG. 4 is a perspective view and FIG. 5 is a lateral view of the end part. As shown therein, a plunger end part 30 includes a plurality of tips 32, 33 and 34 which protrudes toward a tested contact point. At least one of the plurality of tips 32, 33 and 34 is a higher tip 32, and at least another one thereof is a lower tip 34 which is lower than the higher tip 32 in height. For example, the plurality of tips 32, 33 and 34 may have the higher tip 32 and lower tip 34 arranged alternately along a circumferential surface 36 which has an inclined outline with centering a central tip 33.

As shown in FIG. 5, in the plunger end part 30, the higher tip 32 and the lower tip 34 are formed leaving a predetermined step D1 therebetween, and the circumferential surface 36 which is tapered at a predetermined inclination angle θ1 in an axial direction (longitudinal direction) is formed.

Generally, a solder ball which is a tested contact point of a tested object is substantially shaped like a curved or spherical surface, and a hard metal oxide layer or a passivation layer may be formed on the surface of the solder ball. The tip of the plunger end part 30 may perform point-contact rather than surface-contact to effectively contact the spherical surface of the solder ball. That is, the peak of the tips 32, 33 and 34 may maintain their sharpness and easily penetrate the metal oxide layer or the passivation layer through contact pressure (elastic pressure) toward the plunger end part 30 to make good electric contact.

If the tested contact point is a spherical surface like the solder ball, the central tip 33 may not be formed in the plunger end part 30.

If the tested contact point is a flat lead frame, the central tip 33 may be formed in a central area of the plunger end part 30 to increase contact points and reduce contact resistance and to extend the service life of the test probe. Of course, the central tip 33 may not be higher than the higher tip 32.

The tips 32 and 34 which are arranged along the circumferential surface 36 of the plunger end part 30 as in FIG. 5 may include a part of the circumferential surface 36 of the naturally inclined circumference. The tip 33 which is formed in a central part of the tips 32, 33 and 34 may be shaped like a multi-angular pyramid.

The plurality of tips 32, 33 and 34 are divided into groups of the higher tip 32 and the lower tip 34 to contact the tested contact point at time intervals set according to the progress of wear so that the test probe 10 may have an extended service life, i.e., an extension of durability.

In the test probe 10 according to the exemplary embodiment, if the plunger end part 30 contacts physically or elastically the tested contact point of a semiconductor chip, the higher tip 32 and the central tip 33 physically contact the semiconductor chip in the beginning of the test, and are electrically conductive to perform test. Due to repeated contact of a new tested contact point, the peak of the higher tip 32 and lower tip 34 are worn. If the test continues, the peak of the higher tip 32 and lower tip 34 are further worn, and at a certain wear timing, the lower tip 34 that is not worn newly contacts the tested contact point to perform test. Accordingly, the test is fully conducted only with the contact of the higher tip 32 in the beginning of the test. If the peak of the higher tip 32 is worn to a certain degree, the lower tip 34 starts contacting the tested contact point at a predetermined time interval.

The plurality of tips 32, 33 and 34 maybe arranged at different heights. That is, the higher tip 32 and lower tip 34 formed in a circumference may be alternately arranged and the central tip 33 maybe formed at a different height from, or at an equal height to, the height of the higher tip 32 and the lower tip 34. An intermediate tip (not shown) maybe added between the higher and lower tips 32 and 34 formed in the circumference.

Hereinafter, a machining method of the test probe having a plunger end part contacting the tested contact point according to an exemplary embodiment will be described in detail.

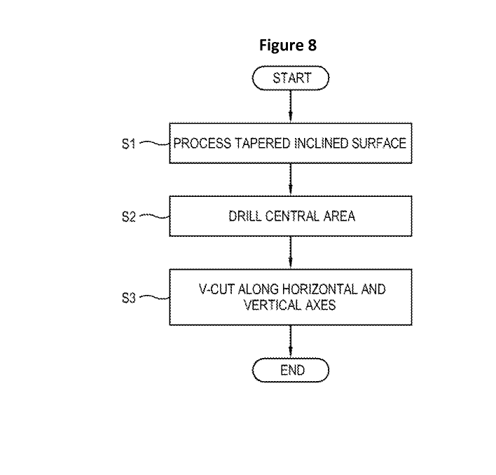

As shown in FIG. 8, a circumferential surface 36 which is adjacent to an end part of a cylindrical plunger is processed to be tapered at a predetermined inclination angle θ1 to form a tapered inclined surface (S1).

A plurality of V-cutting is performed to an end surface of the plunger end part 30 having the tapered inclined surface of the circumferential surface 36 in horizontal and vertical directions at intervals (S3). The gap V-V of the V-cutting may be least close to, or overlap, each other to form a sharp tip. By the V-cutting in horizontal and vertical directions, the higher tip 32, lower tip 34 and central tip 33 may be formed in the plunger end part 30. That is, as in FIG. 4, the tip 34 substantially shaped like a triangular pyramid is formed as a lower tip by greatly overlapping the gap V-V of the V-cutting, and the tip 32 substantially shaped like a rectangular pyramid may be formed as a higher tip by placing the gap V-V of the V-cutting to be least close to each other. The central tip 33 may be formed at the same height as that of the higher tip 32.

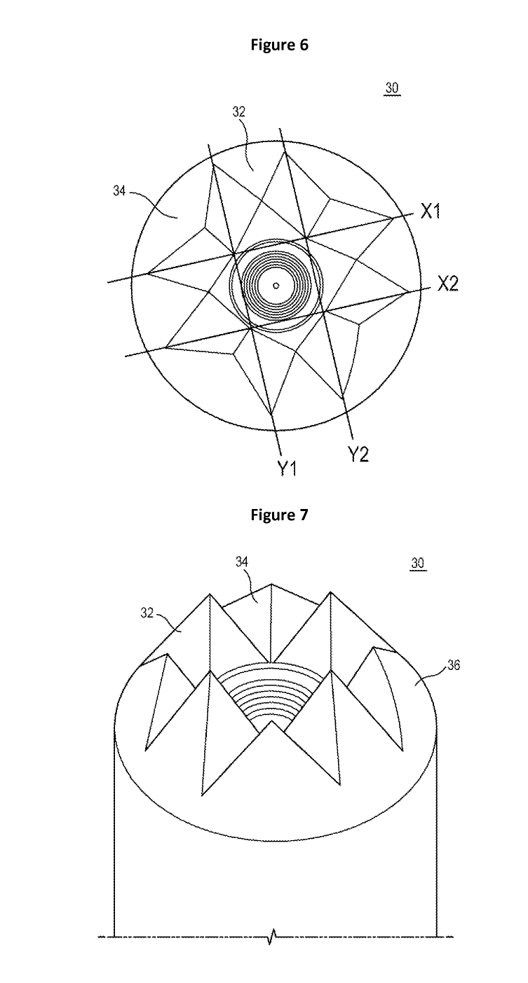

To form the central tip 33 as a lower or intermediate tip, a pre-processing may be performed to form a concave space to perform the V-cutting. In particular, if the central tip 33 is not formed, a hole is formed in a central area in a depth deeper than that of the V-cutting as in FIG. 6 (S2), and then the V-cutting is performed or, drilling may be performed after the central tip 33 is formed.

More specifically, as shown in FIG. 8, the plunger end part 30 is machined to be tapered by processing the circumferential surface 36 at the predetermined tapered inclination angle θ1 and processing the tapered inclined surface (S1); drilling the central area of the plunger end part 30 in a predetermined size not to form the central tip 33 in the central area of the plunger end part 30 (S2); and performing V-cutting in horizontal and vertical directions with respect to the end surface of the plunger end part 30 and forming the higher tip and the lower tip that is lower than the higher tip (S3).

If the end part having a metal material and a predetermined specification is processed at the predetermined tapered inclination angle θ1 at the processing operation S1 to be tapered with the circumferential surface 36 of the plunger end part 30, the processed plunger end part is formed as a beheaded cone tapered at the predetermined inclination angle θ1 up to the area where the peak of the higher tip 32 is formed. The beheaded conical shape tapered at the predetermined inclination angle θ1 makes processing easier and reduces processing time.

The tips 32 and 34 are arranged in a circumferential direction leaving a central blank area, and this is preferable to the case where the tested contact point is spherical.

FIGS . 6 and 7 are enlarged views showing the processed plunger end part 30 without the central tip 33. To remove the central tip 33, the axial center of the plunger end part 30 is drilled in a predetermined diameter and depth. The axial center is drilled after the circumferential surface 36 is processed (S1) and the end surface of the plunger end part 30 remains plane.

Alternatively, the axial center may be drilled before the processing operation (S1) of tapering the circumferential surface 36. The plunger end part 30 having a central blank area with no central tip may be formed by performing V-cutting along the circumference of a cylindrical material.

At the processing in horizontal and vertical axes (S3), the plurality of V-cutting is performed in horizontal and vertical axial directions X1, X2, Y1 and Y2 with respect to the end surface of the plunger end part 30 to form at least one higher tip 32 and at least one lower tip 34 that is lower than the higher tip 32.

The detailed method of forming the higher and lower tips is as follows: V-cutting is performed in the vertical axes Y1 and Y2 and horizontal axes X1 and X2 as in FIGS. 4 and 6. Then, the lower side of the tips 32, 33 and 34 contacts the vertical axes Y1 and Y2 and horizontal axes X1 and X2. The vertical axes Y1 and Y2 and the horizontal axes X1 and X2 are paralleled respectively and are perpendicular to each other. As a result, the higher tip 32 and the lower tip 34 may be alternately formed. That is, a more cut part becomes the lower tip 34 and a less cut part becomes the higher tip 32 during the V-Cutting.

Another method of forming the higher and lower tips 32 and 34 is as follows: V-cutting in horizontal and vertical axes is performed substantially perpendicularly to four tapered surfaces of a beheaded rectangular pyramid with four tapered surfaces. The gap V-V is adjusted to form the higher tip 32 and lower tip 34. That is the higher tip or lower tip may be formed side by side in one of horizontal and vertical directions unlike the case where the V-cutting is performed to a beheaded conic shape.

Accordingly, the circumferential surface 36 is angularly divided at the tapered inclined surface processing operation (S1) and the divided surface is processed flat to form the higher and lower tips 32 and 34. The higher tips 32 are arranged like a cross and the lower tips 34 are arranged between the limbs of the cross.

A test probe according to the embodiment may have a plurality of tips which is formed at different heights. Thus, if a higher tip is worn, a lower tip contacts a tested object to maintain a stable contact for a relatively long time. Thus, reliability of the test improves and the test probe may have an extended life.

Although a few exemplary embodiments have been shown and described, it will be appreciated by those skilled in the art that changes may be made in these exemplary embodiments without departing from the basic principles and spirit of the invention that the plunger end part is divided into groups of the higher end part and lower end part and the end parts sequentially contact a tested object at time intervals according to the progress of wear, the range of which is defined in the appended claims and their equivalents.

1. A test probe comprising:
a plunger end part which contacts a tested contact point; and
a plurality of tips which is provided in the plunge end part and protruds toward the tested contact point, at least one of the plurality of tips being a higher tip and at least another one of the plurality of tips being a lower tip that is lower than the higher tip.

2. The test probe according to claim 1, wherein the higher tip and the lower tip are alternately arranged along a circumferential direction.

3. The test probe according to claim 1, wherein a central tip which is not higher than the higher tip is provided in a central area of the plunger end part.

4. The test probe according to claim 1, wherein the tips are arranged in a circumferential direction leaving a blank area in a center without a tip.

5. A machining method of a test probe which comprises a plunger end part contacting a tested contact point comprising:
processing a circumferential surface of the plunger end part at a predetermined inclination angle to form a tapered inclined surface; and
performing a plurality of parallel V-cuttings in horizontal and vertical directions with respect to an end surface of the plunger end part at intervals to form at least one higher tip and at least one lower tip that is lower than the higher tip.

6. The machining method according to claim 5, wherein the plunger end part is formed with a hole along a central axis.

7. The machining method according to claim 5, further comprising drilling the plunger end part along a central axis before or after processing operation of the tapered inclined surface.

8. The machining method according to claim 5, wherein the tapered inclined surface comprises a beheaded conical surface.

9. The machining method according to 5, wherein the tapered inclined surface comprises a beheaded multi-angular pyramid surface.

10. The test probe according to claim 2, wherein the tips are arranged in a circumferential direction leaving a blank area in a center without a tip.

11. The test probe according to claim 3, wherein the tips are arranged in a circumferential direction leaving a blank area in a center without a tip.

12. The machining method according to claim 6, further comprising drilling the plunger end part along a central axis before or after processing operation of the tapered inclined surface.

13. The machining method according to claim 6, wherein the tapered inclined surface comprises a beheaded conical surface.

14. The machining method according to claim 6, wherein the tapered inclined surface comprises a beheaded multi-angular pyramid surface.
